(19) United States
(12) Patent Application Publication
(10) Pub. No.: US 2022/0165604 A1
(43) Pub. Date: May 26, 2022

(54) MICRO LED ADSORPTION BODY

(71) Applicant: POINT ENGINEERING CO., LTD., Asan (KR)

(72) Inventors: Bum Mo AHN, Suwon (KR); Seung Ho PARK, Hwaseong (KR); Sung Hyun BYUN, Hwaseong (KR)

(21) Appl. No.: 17/430,206

(22) PCT Filed: Feb. 7, 2020
(86) PCT No.: PCT/KR2020/001731

§ 371 Date: Aug. 11, 2021

(30) Foreign Application Priority Data
Feb. 13, 2019 (KR) 10-2019-0016870

(51) Int. Cl. H01L 21/683; H01L 21/67

(52) U.S. Cl. CPC H01L 21/6838; H01L 21/67144

(57) ABSTRACT

A micro LED vacuum adsorption body configured to vacuum-adsorb micro LEDs is proposed. More particularly, the micro LED adsorption body is capable of preventing micro LED damage when adsorbing the micro LEDs.

### TECHNICAL FIELD

The present invention relates to an adsorption body configured to adsorb micro LEDs.

### BACKGROUND ART

Currently, while LCDs still dominate in the display market, OLEDs are rapidly replacing LCDs and emerging as mainstream products. In a current situation where display makers are in a rush to participate in the OLED market, micro light-emitting diode (hereinafter referred to as “micro LED”) displays have emerged as another next-generation display. Liquid crystal and organic materials are respectively the core materials of LCDs and OLEDs, whereas the micro LED display uses an LED chip itself in units of 1 to 100 micrometers (μm) as a light emitting material.

Since the term “micro LED” emerged in the patent “MICRO-LED ARRAYS WITH ENHANCED LIGHT EXTRACTION” in 1999 (Korean Patent No. 10-0731673) disclosed by Cree Inc., research and development is in progress as related research papers based thereon have been published one after another. In order to apply the micro LEDs to a display, the technical problem to be solved requires a customized microchip developed by using a micro LED device on the basis of a flexible material and/or flexible device, and a technique of transferring the micrometer-sized LED chip and mounting the LED chip on a display pixel electrode is required.

In particular, in relation to the transfer of the micro LED device to the display substrate, as the micro LED size is reduced to 1 μm to 100 μm, conventional pick-and-place equipment may not be used, and a transfer head technology for higher precision transfer is required. In relation to the transfer head technology, several structures have been proposed as will be described below, but each proposed technology has several disadvantages.

LuxVue Technology Corp., USA, proposed a method of transferring micro LEDs by using an electrostatic head (Korean Patent Application Publication No. 10-2014-0112486, hereinafter referred to as “Related Art 1”). The transfer principle of Related Art 1 is the principle of applying a voltage to a head part made of silicon material, so as to generate adhesion with micro LEDs by a charging phenomenon. This method may cause a problem with respect to damage to the micro LEDs caused by the charging phenomenon due to voltage applied to the electrostatic head during electrostatic induction.

X-Celeprint Limited, USA, proposed a method of using an elastic polymer material as a transfer head and transferring micro LEDs positioned on a wafer to a desired substrate (Korean Patent Application Publication No. 10-2017-0019415, hereinafter referred to as “Related Art 2”). In this method, there is no problem of damage to the micro LEDs compared to the electrostatic head method, but there are disadvantages in that the micro LEDs may be stably transferred only when adhesive strength of an elastic transfer head is greater than that of a target substrate in a transfer process, and an additional process for electrode formation is required. In addition, continuous maintenance of the adhesive strength of the elastic polymer material serves as a very important factor.

Korea Photonics Technology Institute proposed a method of transferring micro LEDs by using a ciliary adhesive-structured head (Korean Patent No. 10-1754528, hereinafter referred to as “Related Art 3”). However, Related Art 3 has a disadvantage in that it is difficult to produce an adhesive structure of cilia.

Korea Institute of Machinery and Materials proposed a method of transferring micro LEDs by using a roller coated with an adhesive (Korean Patent No. 10-1757404, hereinafter referred to as “Related Art 4”). However, Related Art 4 requires continuous use of the adhesive, and has a disadvantage in that the micro LEDs may be damaged when the roller is pressed.

Samsung Display Co., Ltd proposed a method of transferring micro LEDs to an array substrate by means of electrostatic induction by applying a negative voltage to first and second electrodes of the array substrate in a state where the array substrate is immersed in a solution (Korean Patent Application Publication No. 10-2017-0026959, hereinafter referred to as “Related Art 5”) However, Related Art 5 has a disadvantage in that a separate solution is required so that the micro LEDs are immersed in the solution and transferred to the array substrate, and a subsequent drying process is required.

LG Electronics Inc. proposed a method in which a head holder is arranged between a plurality of pick-up heads and a substrate and a shape of the head holder is allowed to be deformed by movement of the plurality of pick-up heads so that degrees of freedom are provided to the plurality of pick-up heads to move freely (Korean Patent Application Publication No. 10-2017-0024906, hereinafter referred to as “Related Art 6”). However, since Related Art 6 is a method of transferring the micro LEDs to adhesive surfaces of the plurality of pickup heads by applying a bonding material having adhesive strength, there is a disadvantage in that a separate process of applying the bonding material to the pickup heads is required.

In order to solve the above problems of the related inventions, it is necessary to improve the above-mentioned disadvantages while adopting the basic principles adopted by the related inventions as they are. However, since these disadvantages are derived from the basic principles adopted by the related inventions, there is a limit to improving the disadvantages while maintaining the basic principles. Accordingly, the applicant of the present invention intends not only to improve the disadvantages of the related art, but to propose a new method that is not considered at all in the related inventions.

### DOCUMENTS OF RELATED ART

### Patent Document

(Patent Document 1) Korean Patent No. 10-0731673

(Patent Document 2) Korean Patent Application Publication No. 10-2014-0112486

(Patent Document 3) Korean Patent Application Publication No. 10-2017-0019415

(Patent Document 4) Korean Patent No. 10-1754528

(Patent Document 5) Korean Patent No. 10-1757404

(Patent Document 6) Korean Patent Application Publication No. 10-2017-0026959

(Patent Document 7) Korean Patent Application Publication No. 10-2017-0024906

### DISCLOSURE

### Technical Problem

Accordingly, an objective of the present invention is to solve the problems of the micro LED adsorption body proposed so far and provide a micro LED adsorption body capable of effectively adsorbing micro LEDs by providing a member capable of preventing the micro LEDs from being damaged when adsorbing the micro LEDs.

### Technical Solution

According to one aspect of the present invention, a micro LED adsorption body includes: a body part provided with a vacuum suction path; and a buffer part provided on a surface of the body part to mitigate a shock when the micro LEDs are adsorbed.

In addition, the body part may be a non-porous member through which the vacuum suction path penetrates upward and downward.

In addition, the body part may be a porous member.

In addition, the porous member may have random pores.

In addition, the porous member may have vertical pores.

In addition, the porous member may be formed of an anodized film having the vertical pores, and a through-hole having a width greater than the width of each pore may form the vacuum suction path.

In addition, an exposed surface of the buffer part may have adhesive strength.

In addition, an exposed surface of the buffer part may have no adhesive strength.

In addition, the buffer part may include a metal material.

According to another feature of the present invention, a micro LED adsorption body includes: a body part provided with an anodized film having a pore and a through-hole penetrating the anodized film; and a buffer part provided on a surface of the body part to mitigate a shock when micro LEDs are adsorbed.

In addition, an opening of the buffer part may have an area corresponding to that of the through-hole.

### Advantageous Effects

As described above, the micro LED adsorption body according to the present invention is provided with a buffer part to prevent the micro LEDs from being damaged due to direct contact between the micro LED adsorption body and the micro LEDs when the micro LEDs are adsorbed. As a result, it is possible to obtain the effect of lowering occurrence of micro LED damage and increasing the transfer efficiency of the micro LED adsorption body.

### DESCRIPTION OF DRAWINGS

FIG. 1 is a view showing micro LEDs that are transfer targets of exemplary embodiments of the present invention.

FIG. 2 is a view showing a structure of the micro LEDs transferred and mounted on a display substrate according to the exemplary embodiments of the present invention.

FIG. 3 is a view schematically showing a micro LED adsorption body according to a first preferred exemplary embodiment of the present invention.

FIGS. 4 to 7 are views showing the exemplary embodiments of a buffer part of the present invention.

FIG. 8 is a view showing a modified example of the first exemplary embodiment of the present invention.

FIG. 9 is a view schematically showing a micro LED adsorption body according to a second preferred exemplary embodiment of the present invention.

FIGS. 10 and 11 are views schematically showing micro LED adsorption bodies respectively according to a third preferred exemplary embodiment of the present invention.

### MODE FOR INVENTION

The following is merely illustrative of the principles of the invention. Therefore, although not explicitly described or shown herein, those skilled in the art can embody the principles of the invention and devise various devices that are included in the spirit and scope of the invention. In addition, it should be understood that all conditional terms and examples listed herein are, in principle, expressly intended only for the purpose of understanding the inventive concept and are not limited to the specifically enumerated exemplary embodiments and states as such.

The above-described objectives, features, and advantages will become more apparent through the following detailed description in conjunction with the accompanying drawings, and accordingly, those skilled in the art to which the present invention pertains will be able to easily implement the technical idea of the present invention.

The exemplary embodiments described herein will be described with reference to cross-sectional views and/or perspective views, which are ideal illustrative drawings of the present invention. The thicknesses of films and regions, diameters of holes, and the like shown in these drawings are exaggerated for effective description of technical content. The shape of the illustrative drawing may be modified due to manufacturing technology and/or allowable errors. In addition, only a part of the number of micro LEDs shown in the drawings is exemplarily shown in the drawings. Accordingly, exemplary embodiments of the present invention are not limited to the specific form shown, but also include changes in the form generated according to a manufacturing process.

In describing various exemplary embodiments, components that perform the same function will be given the same names and same reference numbers for convenience even though the exemplary embodiments are different from each other. In addition, configurations and operations already described in other exemplary embodiments will be omitted for convenience.

Hereinafter, preferred exemplary embodiments of the present invention will be described in detail with reference to the accompanying drawings.

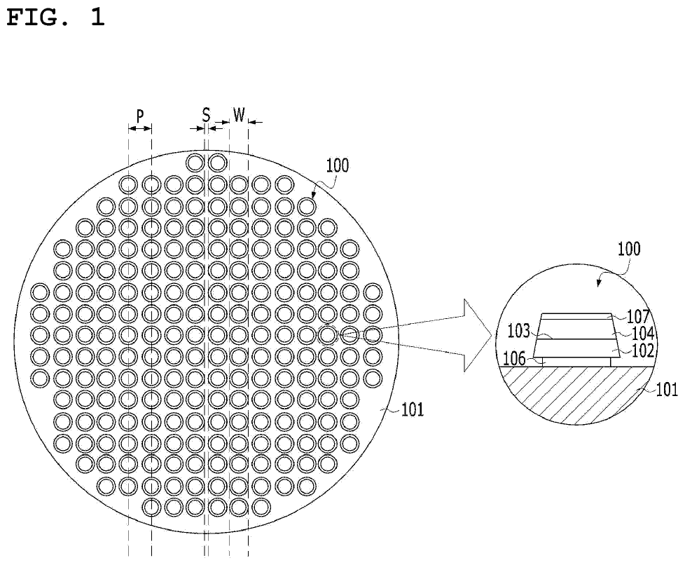

FIG. 1 is a view showing a plurality of micro LEDs 100 to be transferred to a micro LED adsorption body according to a preferred exemplary embodiment of the present invention. The micro LEDs 100 are produced and positioned on a growth substrate 101.

The growth substrate 101 may be formed of a conductive substrate or an insulating substrate. For example, the growth substrate 101 may be formed of at least one of sapphire, SiC, Si, GaAs, GaN, ZnO, Si, GaP, InP, Ge, and Ga2O3.

Each of micro LEDs 100 may include: a first semiconductor layer 102; a second semiconductor layer 104; an active layer 103 formed between the first semiconductor layer 102 and the second semiconductor layer 104; a first contact electrode 106; and a second contact electrode 107.

The first semiconductor layer 102, the active layer 103, and the second semiconductor layer 104 may be formed by using a method such as a metal organic chemical vapor deposition (MOCVD), a chemical vapor deposition (CVD), a plasma-enhanced chemical vapor deposition (PECVD), a molecular beam epitaxy (MBE), and a hydride vapor phase epitaxy (HVPE).

The first semiconductor layer 102 may be implemented as, for example, a p-type semiconductor layer. The p-type semiconductor layer may be made of a semiconductor material selected from, for example, GaN, AlN, AlGaN, InGaN, InN, InAlGaN, AlInN, and the like, the semiconductor material having a composition formula of InxAlyGa1-x-yN (0≤x≤1, 0≤y≤1, 0≤x+y≤1), and may be doped with a p-type dopant such as Mg, Zn, Ca, Sr, and Ba.

The second semiconductor layer 104 may be configured to include, for example, an n-type semiconductor layer. The n-type semiconductor layer may be made of a semiconductor material selected from, for example, GaN, AlN, AlGaN, InGaN, InNInAlGaN, AlInN, and the like, the semiconductor material having a composition formula of InxAlyGa1-x-yN (0≤x≤1, 0≤y≤1, 0≤x+y≤1), and may be doped with a n-type dopant such as Si, Ge, and Sn.

However, the present invention is not limited thereto, and the first semiconductor layer 102 may include the n-type semiconductor layer, and the second semiconductor layer 104 may include the p-type semiconductor layer.

The active layer 103 is a region where electrons and electron holes recombine. As the electrons and electron holes recombine, electron transition to a low energy level occurs in the active layer 103, whereby light having a corresponding wavelength may be generated. The active layer 103 may be configured to include, for example, a semiconductor material having a composition formula of InxAlyGa1-x-yN (0≤x≤1, 0≤y≤1, 0≤x+y≤1), and may be formed in a single quantum well structure or a multi quantum well (MQW) structure. In addition, the active layer 103 may include a quantum wire structure or a quantum dot structure.

The first contact electrode 106 may be formed on the first semiconductor layer 102, and the second contact electrode 107 may be formed on the second semiconductor layer 104. The first contact electrode 106 and/or the second contact electrode 107 may include one or more layers and may be formed of various conductive materials including metals, conductive oxides, and conductive polymers.

A plurality of micro LEDs 100 provided on the growth substrate 101 may be cut along a cutting line by using a laser and the like or separated into individual pieces through an etching process, and may become separable from the growth substrate 101 by a laser lift-off process.

In FIG. 1, “p” refers to a pitch interval between micro LEDs 100, “s” refers to a separation distance between the micro LEDs 100, and “w” refers to a width of each micro LED 100.

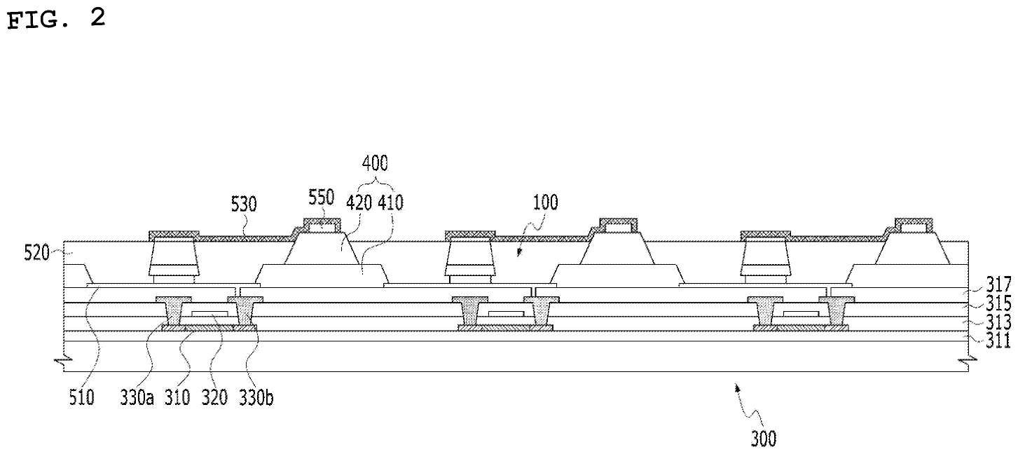

FIG. 2 is a view showing a structure of the micro LEDs transferred to and mounted on a display substrate by a micro LED adsorption body according to a preferred exemplary embodiment of the present invention.

The display substrate 301 may include various materials. For example, the display substrate 301 may be made of a transparent glass material including SiO2 as a main component. However, the display substrate 301 is not necessarily limited thereto, and may be formed of a transparent plastic material so as to have fusibility. The plastic material may be an organic material selected from a group composed of insulating organic materials including: polyethersulfone (PES), polyacrylate (PAR), polyetherimide (PEI), polyethylene naphthalate (PEN), polyethylene terephthalate (PET), polyphenylene sulfide (PPS), polyallylate, polyimide, polycarbonate (PC), cellulose triacetate (TAC), and cellulose acetate propionate (CAP).

In a case of a bottom emission type in which an image is realized in a direction of the display substrate 301, the display substrate 301 should be formed of a transparent material. However, in a case of a top emission type in which an image is realized in a opposite direction to the display substrate 301, the display substrate 301 is not necessarily formed of the transparent material. In this case, the display substrate 301 may be formed of metal.

When the display substrate 301 is formed of metal, the display substrate 301 may include one or more materials selected from a group composed of iron, chromium, manganese, nickel, titanium, molybdenum, stainless steel (SUS), Invar alloy, Inconel alloy, and Kovar alloy, but is not limited thereto.

The display substrate 301 may include a buffer layer 311. The buffer layer 311 may provide a flat surface and block penetration of foreign substances or moisture. For example, the buffer layer 311 may include: inorganic materials such as silicon oxide, silicon nitride, silicon oxynitride, aluminum oxide, aluminum nitride, titanium oxide, or titanium nitride; or organic materials such as polyimide, polyester, and acrylic, and may be formed of a plurality of laminates selected from among the exemplified materials.

A thin film transistor (TFT) may include an active layer 310, a gate electrode 320, a source electrode 330a, and a drain electrode 330b.

Hereinafter, a case where the thin film transistor (TFT) is a top gate type in which the active layer 310, the gate electrode 320, the source electrode 330a, and the drain electrode 330b are sequentially formed will be described. However, the present exemplary embodiment is not limited thereto, and various types of thin film transistors (TFTs) such as a bottom gate type may be adopted.

The active layer 310 may include a semiconductor material, for example, amorphous silicon or poly crystalline silicon. However, the present exemplary embodiment is not limited thereto, and the active layer 310 may include various materials. In an alternative exemplary embodiment, the active layer 310 may include an organic semiconductor material and the like.

In another alternative exemplary embodiment, the active layer 310 may include an oxide semiconductor material. For example, the active layer 310 may include oxides of materials selected from group 12, 13, and 14 metal elements and combinations thereof, the metal elements including: zinc (Zn), indium (In), gallium (Ga), tin (Sn), cadmium (Cd), germanium (Ge), and the like.

A gate insulating layer 313 is formed on the active layer 310. The gate insulating layer 313 serves to insulate the active layer 310 and the gate electrode 320. The gate insulating layer 313 may be formed as a multi-layer or single-layer film made of an inorganic material such as silicon oxide and/or silicon nitride.

The gate electrode 320 is formed on an upper part of the gate insulating layer 313. The gate electrode 320 may be connected to a gate line (not shown) that applies an on/off signal to a thin film transistor (TFT).

The gate electrode 320 may be made of a low-resistance metal material. In consideration of adhesiveness with an adjacent layer, surface flatness of laminated layers, and workability, the gate electrode 320 may be formed as a single layer or a multi-layer made of one or more materials selected from among, for example, aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

An interlayer insulating film 315 is formed on the gate electrode 320. The interlayer insulating layer 315 insulates the source electrode 330a and drain electrode 330b from the gate electrode 320. The interlayer insulating layer 315 may be formed as a multi-layered or a single-layer film made of an inorganic material. For example, the inorganic material may be a metal oxide or a metal nitride. Specifically, the inorganic material may include: silicon oxide (SiO2), silicon nitride (SiNx), silicon oxynitride (SiON), aluminum oxide (Al2O3), titanium oxide (TiO2), tantalum oxide (Ta2O5), hafnium oxide (HfO2), or zinc oxide (ZrO2).

The source electrode 330a and the drain electrode 330b are formed on the interlayer insulating layer 315. The source electrode 330a and the drain electrode 330b may be formed as a single layer or multi-layer made of one or more materials selected from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). The source electrode 330a and the drain electrode 330b are electrically connected to a source region and a drain region of the active layer 310, respectively.

A planarization layer 317 is formed on the thin film transistor (TFT). The planarization layer 317 is formed to cover the thin film transistor (TFT), thereby eliminating a step difference caused by the thin film transistor (TFT) and making a top surface flat. The planarization layer 317 may be formed as a single layer or a multilayer film made of an organic material. Organic materials may include: general-purpose polymers such as polymethylmethacrylate (PMMA) or polystylene (PS), polymer derivatives with phenolic groups, acrylic polymers, imide-based polymers, arylether-based polymers, amide-based polymers, fluorine-based polymers, p-xylene-based polymers, vinyl alcohol-based polymers, and polymer blends thereof. In addition, the planarization layer 317 may be formed of a composite laminate composed of an inorganic insulating film and an organic insulating film.

The first electrode 510 is positioned on the planarization layer 317. The first electrode 510 may be electrically connected to the thin film transistor (TFT). Specifically, the first electrode 510 may be electrically connected to a drain electrode 330b through a contact hole formed in the planarization layer 317. The first electrode 510 may have various shapes, for example, may be patterned and formed in an island shape. A bank layer 400 defining a pixel area may be arranged on the planarization layer 317. The bank layer 400 may include a recess part in which the micro LEDs 100 are to be accommodated. The bank layer 400 may include, for example, a first bank layer 410 forming the recess part. The height of the first bank layer 410 may be determined by the height and viewing angle of the micro LEDs 100. The size (i.e., width) of the recess part may be determined by the resolution, pixel density, and the like of a display device. In the exemplary embodiment, the height of each of micro LEDs 100 may be greater than the height of the first bank layer 410. The recess part may have various cross-sectional shapes such as polygonal, rectangular, circular, conical, oval, and triangular.

The bank layer 400 may further include a second bank layer 420 on an upper part of the first bank layer 410. The first bank layer 410 and the second bank layer 420 may have a step difference, and the width of the second bank layer 420 may be smaller than the width of the first bank layer 410. A conductive layer 550 may be arranged on an upper part of the second bank layer 420. The conductive layer 550 may be arranged in a direction parallel to a data line or a scan line, and is electrically connected to the second electrode 530. However, the present invention is not limited thereto, and the second bank layer 420 may be omitted, and the conductive layer 550 may be arranged on the first bank layer 410. Alternatively, the second bank layer 420 and the conductive layer 550 may be omitted, and the second electrode 530 may be formed over the entire substrate 301 as a common electrode that is common to pixels P. The first bank layer 410 and the second bank layer 420 may include: a material absorbing at least a part of light; a light reflective material; or a light scattering material. The first bank layer 410 and the second bank layer 420 may include an insulating material that is translucent or opaque to visible light (e.g., light in a wavelength range of 380 nm to 750 nm).

For example, the first bank layer 410 and the second bank layer 420 may include: thermoplastic resins such as polycarbonate (PC), polyethylene terephthalate (PET), polyether sulfone, polyvinyl butyral, polyphenylene ether, poly amide, polyetherimide, norbornene system resin, methacrylic resin, and a cyclic polyolefin type; thermosetting resins such as epoxy resin, phenol resin, urethane resin, acrylic resin, vinyl ester resin, imide resin, urethane resin, urea resin, and melamine resin; or organic insulating materials such as polystyrene, polyacrylonitrile, and polycarbonate, but the present invention is not limited thereto.

As another example, the first bank layer 410 and the second bank layer 420 may be formed of an inorganic insulating material such as an inorganic oxide or an inorganic nitride, the inorganic insulating material including SiOx, SiNx, SiNxOy, AlOx, TiOx, TaOx, and ZnOx, but the present invention is not limited thereto. In the exemplary embodiment, the first bank layer 410 and the second bank layer 420 may be formed of an opaque material, such as a black matrix material. The insulating black matrix material may include: organic resins; glass pastes; resins or pastes including black pigments; metal particles such as nickel, aluminum, molybdenum, and alloys thereof; metal oxide particles (e.g., chromium oxide); metal nitride particles (e.g., chromium nitride); and the like. In a modified example, the first bank layer 410 and the second bank layer 420 may be a distributed Bragg reflector (DBR) having a high reflectance or a mirror reflector formed of metal.

The micro LEDs 100 are arranged in the recess part. The micro LEDs 100 may be electrically connected to the first electrode 510 in the recess part.

Each of micro LEDs 100 emits light having wavelengths of colors such as red, green, blue, and white, and white light may also be implemented by using a fluorescent material, or by combining the colors. Each of micro LEDs 100 has a size of 1 μm to 100 μm. An individual micro LED 100 or a plurality of micro LEDs 100 is picked up from the growth substrate 101 by a transfer head according to the exemplary embodiment of the present invention, so as to be transferred to the display substrate 301, whereby the micro LEDs 100 may be accommodated in the recess part of the display substrate 301.

Each of micro LEDs 100 includes: a p-n diode, a first contact electrode 106 arranged on one side of the p-n diode, and a second contact electrode 107 arranged on an opposite side to the first contact electrode 106. The first contact electrode 106 may be connected to the first electrode 510, and the second contact electrode 107 may be connected to the second electrode 530.

The first electrode 510 may include: a reflective film formed of Ag, Mg, Al, Pt, Pd, Au, Ni, Nd, Ir, Cr, and a compound thereof; and a transparent or translucent electrode layer formed on the reflective film. The transparent or translucent electrode layer may be provided with at least one or more materials selected from a group including: indium tin oxide (ITO), indium zinc oxide (IZO), zinc oxide (ZnO), indium oxide (In2O3), indium gallium oxide (IGO), and aluminum zinc oxide (AZO).

A passivation layer 520 surrounds the micro LEDs 100 in the recess part. The passivation layer 520 fills a space between the bank layer 400 and each of micro LEDs 100 so as to cover the recess part and the first electrode 510. The passivation layer 520 may be formed of an organic insulating material. For example, the passivation layer 520 may be formed of acrylic, poly(methyl methacrylate) (PMMA), benzocyclobutene (BCB), polyimide, acrylate, epoxy, polyester, and the like, but is not limited thereto.

The passivation layer 520 is formed with a height that does not cover an upper part of each micro LED 100, for example, the second contact electrode 107, so that the second contact electrode 107 is exposed. A second electrode 530 electrically connected to an exposed second contact electrode 107 of each micro LED 100 may be formed on the upper part of the passivation layer 520.

The second electrode 530 may be arranged on each micro LED 100 and the passivation layer 520. The second electrode 530 may be formed of a transparent conductive material such as ITO, IZO, ZnO, or In2O3.

The micro LED adsorption body of the present invention may adsorb the micro LEDs 100 by using vacuum suction force. The micro LED adsorption body has no limitation on a structure thereof as long as the structure is capable of generating the vacuum suction force.

The micro LED adsorption body may be a transfer head transferring the micro LEDs or a carrier receiving the micro LEDs 100 from a growth substrate 101 or a temporary substrate, and may include a micro LED transfer head that absorbs micro LEDs 100 of a first substrate such as the growth substrate 101 or the temporary substrate to transfer the micro LEDs 100 to a second substrate such as the display substrate 301.

The micro LED adsorption body of the present invention may be provided with a buffer part on a surface of a member generating a vacuum suction force for adsorbing the micro LEDs 100. Due to this configuration, when micro LEDs are adsorbed, a structure in which the buffer part and the micro LEDs 100 are in direct contact is formed, thereby preventing the problem of damaging the micro LEDs 100.

In a case of the member generating the vacuum suction force of the micro LED adsorption body, the member may be formed of a material with high rigidity in order to prevent product deformation. Accordingly, when direct contacting with micro LEDs 100, the member may cause a problem of damaging the micro LEDs 100.

In the present invention, the buffer part is provided on the surface of the member generating the vacuum suction force of the micro LED adsorption body, so that it is possible to provide the structure in which the buffer part is positioned between the micro LED adsorption body and the micro LEDs 100 when adsorbing the micro LEDs. Accordingly, when the micro LEDs 100 are adsorbed, the buffer part and the micro LEDs 100 are in direct contact, and the shock that causes damage to the micro LEDs 100 is mitigated by the buffer part, thereby preventing the problem of damaging the micro LEDs.

Hereinafter, as a micro LED adsorption body 1 capable of adsorbing the micro LEDs 100 by using the vacuum suction force, a micro LED transfer head is exemplified and described as an exemplary embodiment.

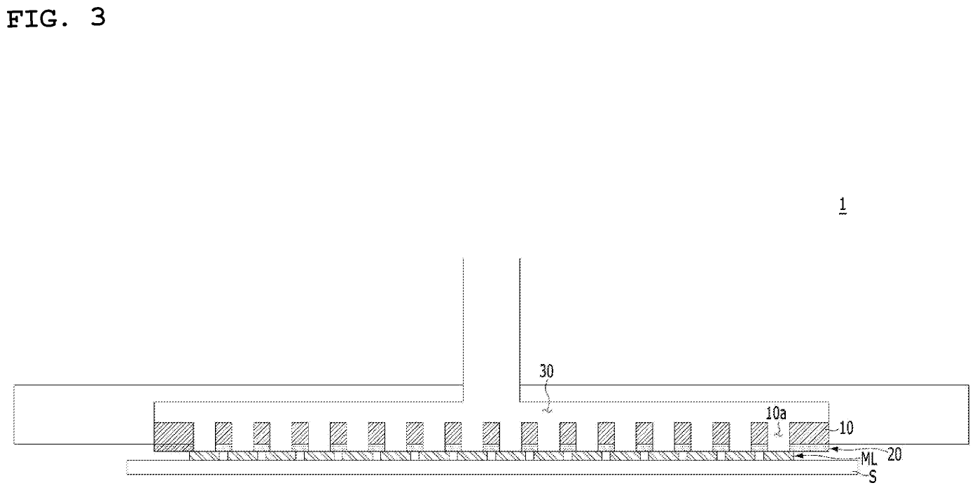

Hereinafter, preferred exemplary embodiments of the present invention will be described with reference to FIGS. 3 to 11.

FIG. 3 is a view showing a state in which the micro LED adsorption body 1 according to the first preferred exemplary embodiment of the present invention is adsorbing the micro LEDs 100. The substrate S on which the micro LEDs 100 are chipped in FIG. 3 may be a first substrate (e.g., growth substrate 101 or temporary substrate) or a second substrate (e.g., display substrate 301).

As shown in FIG. 3, the micro LED adsorption body 1 may be configured to include: a body part 10 provided with a vacuum suction path 10a; a buffer part 20 provided on a surface of the body part 10; and a vacuum chamber 30 provided on an upper part of the body part 10.

The vacuum chamber 30 serves to apply vacuum to the vacuum suction path 10a of the body part 10 or release the vacuum applied to the vacuum suction path 10a according to the operation of a vacuum port (not shown). A structure for combining the vacuum chamber 30 to the body part 10 is not limited as long as the structure is suitable for preventing leakage of vacuum to other parts when applying the vacuum to the body part 10 or releasing the applied vacuum.

When the micro LEDs 100 are adsorbed by vacuum, the vacuum applied to the vacuum chamber 30 is transferred to the vacuum suction path 10a of the body part 10 to generate a vacuum adsorption force for the micro LEDs 100. Meanwhile, when the micro LEDs 100 are detached, as the vacuum applied to the vacuum chamber 30 is released, the vacuum is also released in the vacuum suction path 10a of the body part 10, so that the vacuum adsorption force for the micro LEDs 100 is removed.

The body part 10 in which the vacuum suction path 10a is provided may be a non-porous member. In this case, the vacuum suction path 10a may be formed through the upper and lower parts of the body part 10.

Each vacuum suction path 10a may be formed to correspond to the number and location of the micro LEDs 100 arranged on a first substrate (e.g., growth substrate 101 or temporary substrate) or a second substrate (e.g., display substrate 301). Alternatively, the vacuum suction paths 10a may be formed at a regular pitch interval in order to selectively adsorb the micro LEDs 100.

As shown in FIG. 3, the surface of the body part 10 is provided with the buffer part 20. The buffer part 20 may be provided on the surface of the body part 10 and may be provided around the vacuum suction path 10a. Such a buffer part 20 is provided on the surface of the body part 10 except for an opening of the vacuum suction path 10a so that the opening 20a may be formed by the vacuum suction path 10a. Accordingly, the openings 20a of the buffer part 20 may be formed at the same number and regular intervals as those of the vacuum suction paths 10a, and may be respectively formed at positions each corresponding to the vacuum suction paths 10a.

In addition, the area of the opening 20a of the buffer part 20 may be formed to have the same area as the area of the vacuum suction path 10a. The vacuum suction path 10a may be formed by etching the body part 10 after the buffer part 20 is provided on the body part 10.

In this case, the buffer part 20 at the time of being attached to the surface of the body part 10 may be in a form in which the opening 20a is formed or in a form in which the opening 20a is not formed. When the buffer part 20 is provided with the buffer part 20 on the surface of the body part 10 in the form in which the opening 20a is formed in the buffer part 20 so as to form the vacuum suction path 10a, the vacuum suction path 10a having the same area as that of the opening of the buffer part 20 may be formed at the same position as the opening 20a of the buffer part 20. Alternatively, the buffer part 20 in the form in which the opening 20a is not formed may be provided on the surface of the body part 10. In this case, the opening 20a of the buffer part 20 and the vacuum suction path 10a may be formed by laser processing or by etching the buffer part 20 and body part 10 at the same time. Accordingly, the area of the opening 20a of the buffer part 20 and the area of the vacuum suction path 10a may be formed to be the same.

Meanwhile, after the vacuum suction path 10a is first formed in the body part 10, the buffer part 20 may be provided on the surface of the body part 10. In this case, the vacuum suction path 10a may be formed by laser processing or by etching. When the buffer part 20 is provided after first forming the vacuum suction path 10a on the surface of the body part 10, the area of the opening 20a of the buffer part 20 may be formed to be the same as or smaller than the area of the vacuum suction path 10a.

Even when the area of the opening 20a of the buffer part 20 is smaller than the area of the vacuum suction path 10a, the micro LEDs 100 are sufficiently adsorbed by the vacuum pressure formed by vacuum applied through the vacuum suction path 10a. Therefore, when the buffer part 20 is provided in the body part 10 in which the vacuum suction path 10a is formed, even when the area of the opening 20a of the buffer part 20 is the same as or smaller than the area of the vacuum suction path 10a, there is no problem.

In addition, the area of the opening 20a of the buffer part 20 may be formed to be smaller than the horizontal area of an upper surface of each micro LED 100. When the area of the opening 20a of the buffer part 20 is formed to be smaller than the horizontal area of the upper surface of each micro LED 100, the present invention may be implemented in the exemplary embodiment as shown in FIG. 3.

The buffer part 20 having each opening 20a with such an area as above may prevent the problem that the micro LEDs 100 are damaged due to the shock caused by the direct contact between the body part 10 and the micro LEDs 100 when the micro LEDs 100 are adsorbed to the opening side of the vacuum suction path 10a by the vacuum applied to the vacuum suction path 10a.

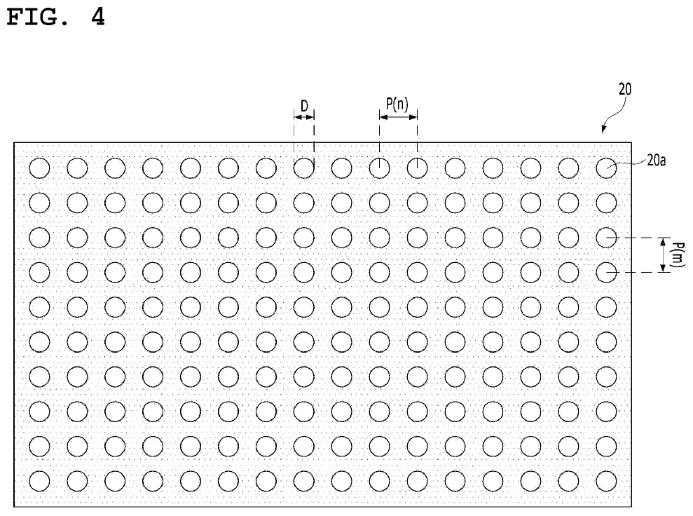

Hereinafter, the exemplary embodiment of the buffer part 20 of the present invention will be described with reference to FIGS. 4 to 7. The openings 20a of the buffer part 20 of the present invention with reference to FIGS. 4 to 7 below is illustrated as having a circular cross-section, but may have a rectangular cross-section, and the shape of the cross-section of the buffer part 20 is not limited thereto.

FIG. 4 is a view showing, as viewed from below, the buffer part 20 provided in the micro LED adsorption body 1 according to the first exemplary embodiment of the present invention shown in FIG. 3.

When a pitch interval in a column direction of the micro LEDs 100 on the growth substrate 101 shown in FIG. 1 is P(n) and a pitch interval in a row direction thereof is P(m), the openings 20a of the buffer part 20 may be formed at the same pitch intervals as those pitch intervals of the micro LEDs 100 on the growth substrate 101. Since the openings 20a of the buffer part 20 are respectively formed at the same number and regular pitch intervals at positions corresponding to the vacuum suction paths 10a of the body part 10, the vacuum suction paths 10a may also be formed at the same pitch intervals as the pitch intervals of the micro LEDs 100 on the growth substrate 101.

According to this configuration, the micro LED adsorption body 1 provided with the buffer part 20 on the surface of the body part 10 having the vacuum suction paths 10a may vacuum adsorb the entire micro LED 100 on the growth substrate 101 all at once.

The area of each opening 20a of the buffer part 20 may be formed to be smaller than the horizontal area of an upper surface of each micro LED 100 on the growth substrate 101. Therefore, the remaining horizontal area of the upper surface of each micro LED 100 excluding the area of the opening 20a of the buffer part 20 from the horizontal area of the upper surface of each micro LED 100 is in contact with the exposed surface of the buffer part 20, so that each micro LED 100 may be adsorbed to the micro LED adsorption body 1. Since the part in direct contact with micro LEDs 100 is the exposed surface of the buffer part 20, the micro LEDs 100 may be adsorbed to the micro LED adsorption body 1 without being damaged.

The exposed surface of the buffer part 20 in direct contact with the micro LEDs 100 may have adhesive strength. Compared to the configuration in which adhesive strength is not present, the case in which the adhesive strength is present on the exposed surface of the buffer part 20 may be more advantageous in terms of adsorption of the micro LEDs 100.

Specifically, the micro LED adsorption body 1 may generate a vacuum adsorption force capable of vacuum adsorbing the micro LEDs 100 with the vacuum applied to the vacuum suction paths 10a. However, when the vacuum applied to the vacuum suction paths 10a is low vacuum, the vacuum suction force for adsorbing the micro LEDs 100 may be weakly generated. This weak vacuum suction force may cause a problem that the micro LEDs 100 are not properly adsorbed to the micro LED adsorption body 1 when adsorbing the micro LEDs 100.

However, in the present invention, by making adhesive strength that is present on the exposed surface of the buffer part 20 to which at least a part of the upper surface of each micro LED 100 is in contact, the micro LEDs 100 may be adsorbed without any problem even when the weak vacuum adsorption force is generated in the micro LED adsorption body 1.

Meanwhile, the exposed surface of the buffer part 20 in direct contact with micro LEDs 100 may not have the adhesive strength. In this case, the vacuum adsorption force for the micro LED adsorption body 1 to adsorb micro LEDs 100 may be sufficiently generated.

The exposed surface of the buffer part 20 is surface-treated, or a separate layer is provided on the exposed surface of the buffer part 20, whereby the adhesive strength may not be allowed to exist on the exposed surface of the buffer part 20.

Compared to the configuration in which the adhesive strength is present, the case in which the adhesive strength is not present on the exposed surface of the buffer part 20 may be more advantageous in terms of removing the micro LEDs 100 from the micro LED adsorption body 1.

Specifically, when the micro LED adsorption body 1 is in a state in which the micro LEDs 100 are adsorbed with a sufficient vacuum adsorption force, at least a part of the upper surface of each micro LED 100 may be in a state of being adsorbed in contact with the exposed surface of the buffer part 20. In this case, the vacuum applied to the vacuum suction paths 10aof the micro LED adsorption body 1 may be released so as to remove the micro LEDs 100 from the micro LED adsorption body 1. Since there is no adhesive strength on the exposed surface of the buffer part 20, the micro LEDs 100 may be easily removed as the vacuum of the micro LED adsorption body 1 is released.

The buffer part 20 may include a metal material. Accordingly, it is possible to effectively remove the electrostatic force that interferes with the micro LED 100 transfer process of the micro LED adsorption body 1 in advance.

Specifically, in the process of transferring the micro LEDs 100 through the micro LED adsorption body 1, due to charging caused by friction and the like, electrostatic force may be unintentionally generated between the first substrate (e.g., growth substrate 101 or temporary substrate) and the micro LED adsorption body 1, or between the second substrate (e.g., display substrate 301) and the micro LED adsorption body 1.

Even when the electrostatic force is generated by a small electric charge, such an unintentional electrostatic force has a large effect on each micro LED 100 having a size of 1 to 100 micrometers (μm).

In other words, after the micro LED adsorption body 1 adsorbs the micro LEDs 100 from the first substrate, when the electrostatic force is generated in an unloading process of mounting the micro LEDs 100 to the second substrate, there occurs a problem that the micro LEDs 100 are adhered to the micro LED adsorption body 1 and unloaded to the second substrate with a misaligned position, or the unloading itself is not performed.

In this situation, in the present invention, the buffer part 20 is configured to include a metal material and provides the metal material on the surface of the body part 10, the negative electrostatic force may be removed, which is generated in the process of transferring the micro LEDs 100 through the micro LED adsorption body 1.

By varying the pitch intervals in the column direction and the row direction of the openings 20a of the buffer part 20 shown in FIG. 4, different openings 20a of the buffer part 20 may be provided. Since the openings 20a of the buffer part 20 is formed in the same manner as the vacuum suction paths 10a provided in the body part 10, the pitch intervals in the column direction and the row direction of the openings 20a of the buffer part 20 shown in FIGS. 4 to 7 may be the same as the pitch intervals in the column direction and row direction of the vacuum suction paths 10a provided in the body part 10.

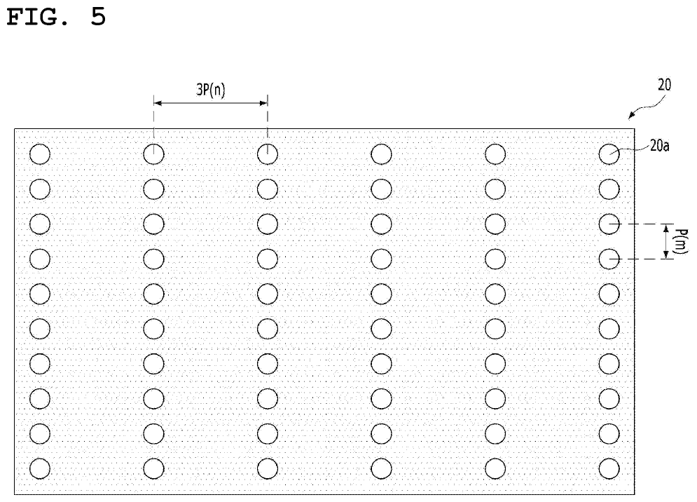

FIGS. 5 to 7 are views respectively showing exemplary embodiments in which the pitch intervals in the column direction or the row direction of the buffer part 20 of the present invention are made different.

As shown in FIG. 5, when a pitch interval in a column direction of the micro LEDs 100 on the growth substrate 101 is P(n) and a pitch interval in a row direction thereof is P(m), each opening 20a of the buffer part 20 may have a pitch interval of 3P(n) in the column direction and a pitch interval of P(m) in the row direction. Here, 3P(n) means three times the P(n) of the pitch interval in the column direction shown in FIG. 4. According to such a configuration, only the micro LEDs 100 respectively corresponding to the columns with three times the pitch interval may be vacuum-adsorbed and transferred. Here, micro LEDs 100 transferred to a column with three times the pitch interval may be any one of red, green, blue, and white LEDs. According to this configuration, the micro LEDs 100 of the same luminous color mounted on the second substrate (e.g., display substrate 301) may be transferred by separating the micro LEDs 100 from each other to be spaced apart at intervals of 3P(n).

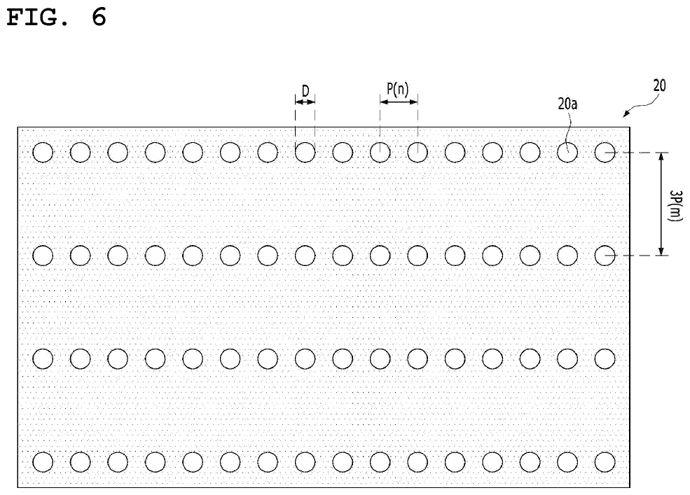

As shown in FIG. 6, when the pitch interval in the column direction of the micro LEDs 100 on the growth substrate 101 is P(n) and the pitch interval in the row direction thereof is P(m), each opening 20a of the buffer part 20 may have a pitch interval of 3P(n) in the column direction and a pitch interval of P(m) in the row direction. Here, 3P(m) means three times the P(m) of the pitch interval in the row direction shown in FIG. 4. According to such a configuration, only the micro LEDs 100 respectively corresponding to the rows with three times the pitch interval may be vacuum-adsorbed and transferred. Here, micro LEDs 100 transferred to a column with three times the pitch interval may be any one of red, green, blue, and white LEDs. According to this configuration, the micro LEDs 100 of the same luminous color mounted on the display substrate 301 may be transferred at intervals of 3P(m).

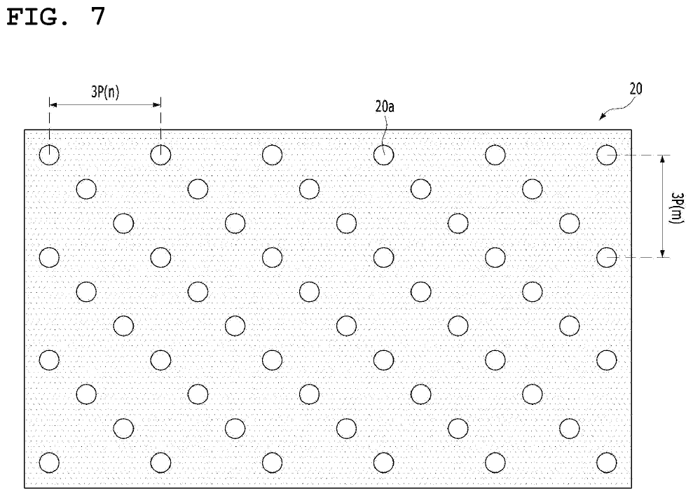

As shown in FIG. 7, when the pitch interval in the column direction of the micro LEDs 100 on the growth substrate 101 is P(n) and the pitch interval in the row direction thereof is P(m), the openings 20a of the buffer part 20 may be formed in a diagonal direction so that the pitch intervals in the column and row directions are respectively 3P(n) and 3P(m). Here, the micro LEDs 100 transferred to the row with three times the pitch interval and the column with three times the pitch interval may be any one of red, green, blue, and white LEDs. According to this configuration, the same micro LEDs 100 mounted on the display substrate 301 are spaced apart at intervals of 3P(n) and 3P(m), so that the micro LEDs 100 of the same luminous color may be transferred in the diagonal direction.

As shown in FIGS. 4 to 7, the buffer part 20 may be provided on the entire surface of the body part 10 except for the openings of the vacuum suction paths 10a and provided on at least a part of the surface of the body part 10, wherein the buffer part 20 may be provided in a form surrounding the openings of the vacuum suction paths 10a.

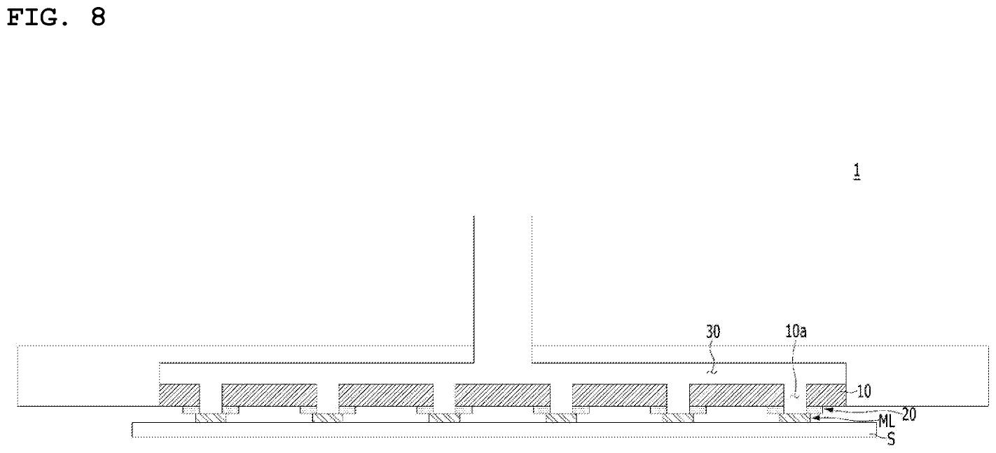

FIG. 8 is a view showing a modified example of the first exemplary embodiment of the present invention. The micro LED adsorption bodies 1 of the modified examples are different from each other in that the vacuum suction paths 10a provided in the body part 10 are provided with a distance three times the pitch interval in the column direction of the vacuum suction path 10a of the micro LED adsorption body 1 of the first exemplary embodiment shown in FIG. 3 and in that the buffer part 20 provided on the surface of the body part 10 is provided to surround the openings of the vacuum suction paths 10a on at least a part of the surface of the body part 10.

In the case of the modified example shown in FIG. 8, the openings 20a of the buffer part 20 may be formed at the same pitch intervals as in FIGS. 5 and 7.

As shown in FIG. 8, the buffer part 20 is provided to surround the openings of the vacuum suction paths 10a, wherein the buffer part 20 may be provided only on at least a part of the surface of the body part 10. In this case, the buffer part 20 may be provided only on at least the part of the surface of the body part 10 to surround only the periphery of the opening of each vacuum suction path 10a and provided to each correspond to the vacuum suction path 10a.

In this case, the opening 20a of the buffer part 20 is formed smaller than the horizontal area of the upper surface of each micro LED 100, and the remaining area of the buffer part 20 excluding the opening 20a of the buffer part 20 is the same as or larger than the area excluding the area of the opening 20a of the buffer part 20 from the horizontal area of the upper surface of each micro LED 100. According to this configuration, when the micro LEDs 100 are adsorbed by the micro LED adsorption body 1, the buffer part 20 may mitigate the shock that causes the micro LEDs 100 to be damaged.

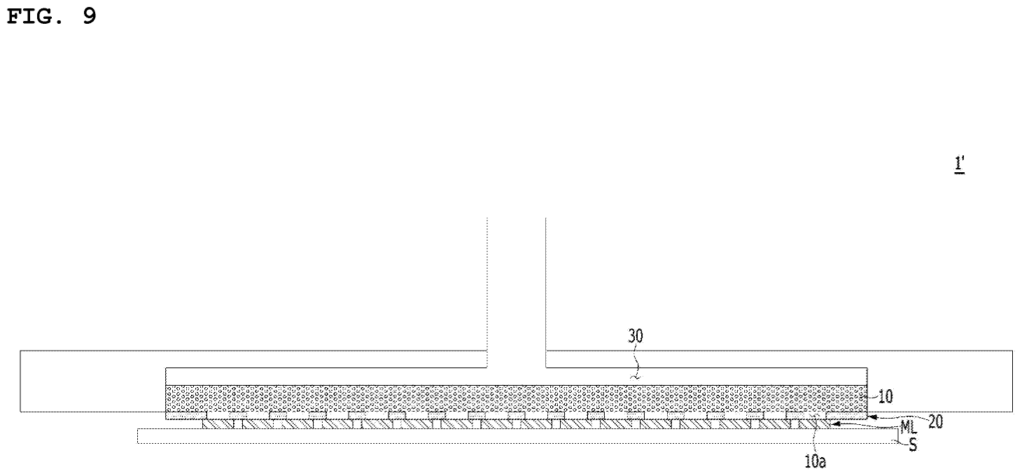

FIG. 9 is a view schematically showing a micro LED adsorption body 1′ according to a second preferred exemplary embodiment of the present invention. The second exemplary embodiment is different from the first exemplary embodiment in that the body part 10 on which the vacuum suction paths 10a are provided is a porous member. Since all configurations except for the above difference are the same, the description of the same configuration will be omitted with reference to the above description.

As shown in FIG. 9, the micro LED adsorption body 1′ of the second exemplary embodiment may be configured to include: a body part 10 provided with vacuum suction paths 10a; a buffer part 20 provided on a surface of the body part 10; and a vacuum chamber 30.

As shown in FIG. 9, the body part 10 may be a porous member. The porous member is configured to include a material including a large number of pores therein, and may be configured in the form of powder, thin film/thick film, and bulk material having a porosity of about 0.2 to 0.95 with a predetermined arrangement or disordered pore structure. According to sizes of pores, the pores of the porous member may be classified into micro pores with a diameter of 2 nm or less, meso pores with a diameter of 2 to 50 nm, and macro pores with a diameter of 50 nm or more, and the porous member includes at least some of these pores. The porous member may be classified into organic, inorganic (e.g., ceramic), metal, and hybrid porous materials according to its constituent elements. In terms of shapes, the porous member may be a powder, a coating film, or a bulk material. In a case of powder, various shapes such as spherical shape, hollow sphere shape, fiber type, and tube type are possible to be used, and in some cases, the powder may be used as it is, but it is also possible to use the powder as a starting material to prepare the shapes of coating film or bulk material.

The porous member may have random pores. The porous member having the random pores may have a disordered pore structure. When pores of a porous member have a disordered pore structure, a plurality of pores are connected to each other inside the porous member to form flow paths connecting the top and bottom of the porous member. Such a porous member may be made porous by sintering a binder that combines aggregates with each other, the aggregates being composed of inorganic material powder/granules. In this case, in the porous member, the plurality of pores is irregularly connected to each other to form gas flow paths, and a surface and an opposite surface of the porous member communicate with each other through the gas flow paths. The body part 10 made of the porous member by the gas flow paths may be provided with vacuum suction paths.

A buffer part 20 may be provided on the surface of the body part 10 as above. As described above, in the porous member having random pores, the gas flow paths are formed by the pores that are irregularly connected to each other so that the vacuum suction paths may be provided. Accordingly, as shown in FIG. 9, in the porous member having random pores, the vacuum suction paths may be provided throughout the interior of the porous member by the pores irregularly connected to each other.

In the second exemplary embodiment, since the vacuum suction paths are provided throughout the interior of the porous member having the random pores, the entire lower surface of the porous member may be formed as an adsorption surface capable of adsorbing the micro LEDs 100. Therefore, when the buffer part 20 is provided on the surface of the porous member, the part in which the opening 20a of the buffer part 20 is positioned may become the micro LED adsorption area for substantially adsorbing the micro LEDs 100. In other words, in the second exemplary embodiment, by providing the buffer part 20 on the surface of the porous member, the adsorption area for adsorbing the micro LEDs 100 may be practically limited.

The buffer part 20 has a plurality of openings 20a and non-opening parts, or may be provided in an independent form at positions each corresponding to micro LEDs 100 to be adsorbed at the same pitch interval as the pitch interval of each micro LED 100 to be adsorbed.

When the buffer part 20 is provided in the form having the plurality of openings 20a and non-opening parts, as shown in FIG. 9, the buffer part 20 may be configured such that each non-opening part in which the opening 20a of the buffer part 20 is not formed may block some surfaces of the lower part of the porous member having random pores and a large vacuum adsorption force may be allowed to be generated in the opening 20a of the buffer part 20. The buffer part 20 having the above structure may have not only a function of preventing the micro LEDs 100 from being damaged by mitigating the shock when adsorbing the micro LEDs 100, but also a function of masking that may increase the vacuum adsorption force of the micro LED adsorption area.

Meanwhile, the buffer part 20 may be provided in an independent form and may have an opening 20a, and a vacuum adsorption force capable of adsorbing the micro LEDs 100 through the opening 20a may be generated. When the buffer part 20 is provided in the independent form, since the buffer part is provided at positions each corresponding to the micro LEDs 100, a plurality of buffer part 20 may be provided on the surface of the body part 10. Such a buffer part 20 is in contact with at least a part of the upper surface of each micro LED 100 so that the micro LEDs 100 may be adsorbed to the micro LED adsorption body 1 while mitigating the shock of the micro LEDs 100.

When the buffer part 20 is provided in the porous member having random pores, as described above, a buffer part 20 having a plurality of openings 20a and non-opening parts or an independent buffer part having an opening 20a may be provided, but preferably, the micro LEDs 100 may be effectively adsorbed by providing the buffer part 20 having the plurality of openings 20a and non-opening parts so as to form a larger vacuum pressure through the openings 20a than before.

Meanwhile, the body part 10 may be a porous member having vertical pores. The porous member having the vertical pores may be implemented through laser or etching. The porous member having the vertical pores may form air flow paths by means of pores having a vertical shape and penetrating the top and bottom of the porous member.

The vertical pores of the porous member may be vacuum suction paths in which the vacuum adsorption force for adsorbing the micro LEDs 100 is generated. Alternatively, the porous member having the vertical pores may have separate vacuum suction paths each having a width thereof greater than the width of the vertical pores.

The surface of the porous member having vertical pores may include: a buffer part 20 having a plurality of openings 20a and non-opening parts; or a buffer part 20 having openings 20a that are independently provided at positions respectively corresponding to the micro LEDs 100 to be adsorbed, the openings 20a having the same pitch intervals as the micro LEDs 100 to be adsorbed.

When the buffer part 20 is provided on the surface of the porous member in which vertical pores serve as vacuum suction paths, the positions where the openings 20a of the buffer part 20 are formed may be substantially a micro LED adsorption area that adsorbs the micro LEDs 100.

Meanwhile, when the separate vacuum suction paths each having a width thereof greater than the width of the vertical pore is provided in the porous member having the vertical pores, openings 20a of the buffer part 20 may be provided at positions where the openings 20a respectively correspond to the vacuum suction paths 10a.

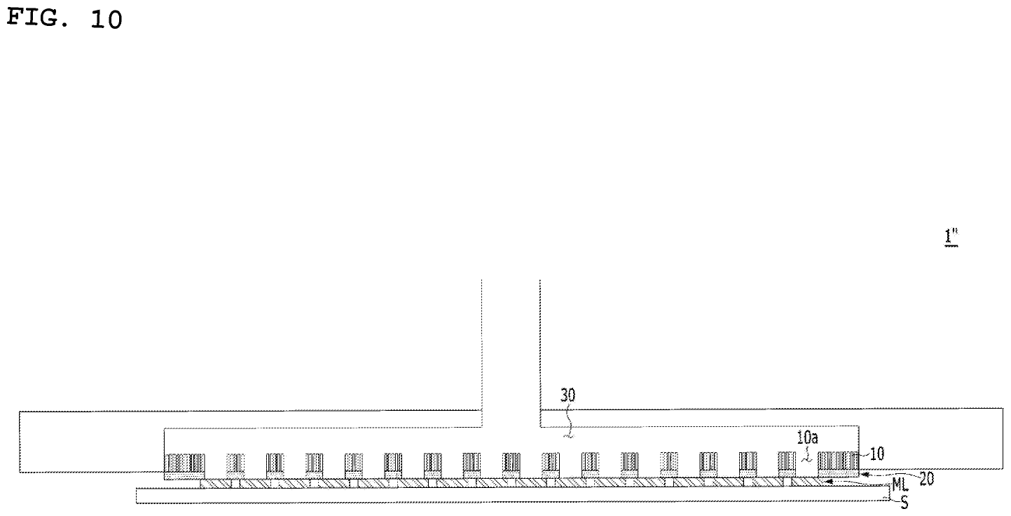

As an example, the porous member having vertical pores may be formed of an anodized film having vertical pores. Hereinafter, with reference to FIG. 10, the micro LED adsorption body 1″ according to a third exemplary embodiment of the present invention in which the body part 10 is formed of the anodized film having vertical pores will be described.

FIG. 10 is a view schematically showing the micro LED adsorption body 1″ according to the third preferred exemplary embodiment of the present invention. The third exemplary embodiment is different from the first exemplary embodiment in that the body part 10 is formed of the anodized film having pores. Except for this configuration, since all configurations are the same as those of the first exemplary embodiment, a detailed description of the same configuration will be omitted with reference to the above description.

As shown in FIG. 10, the third exemplary embodiment is configured to include: a body part 10 provided with an anodized film having pores and a through-hole 10a penetrating the anodized film; a buffer part 20 provided on a surface of the body part 10; and a vacuum chamber 30.

The anodized film refers to a film formed by anodizing a metal as a base material, and the pores refer to holes formed in a process of forming the anodized film by anodizing the metal. For example, in a case where a base metal is aluminum (Al) or an aluminum alloy, when the base material is anodized, an anodized film made of anodized aluminum (Al2O3) material is formed on a surface of the base material. As described above, the anodized film formed is divided into a barrier layer in which pores are not formed and a porous layer in which the pores are formed. The barrier layer is positioned on an upper part of the base material, and the porous layer is positioned on an upper part of the barrier layer. In this way, in the base material having a surface on which an anodized film having a barrier layer and a porous layer is formed, when the base material is removed, only the anodized film made of anodized aluminum oxide (Al2O3) remains.

The anodized film has pores each configured to have a uniform diameter, formed in a vertical shape, and arranged regularly. Accordingly, when the barrier layer is removed, the pores have a structure vertically penetrating upward and downward, and through the pores, it is easy to generate vacuum pressure in the vertical direction.

As shown in FIG. 10, the anodized film as above is provided with a through-hole 10a penetrating the anodized film upward and downward. The through-hole 10a may be formed to have a width greater than the width of the pore. Vacuum suction paths 10a for substantially adsorbing the micro LEDs 100 respectively may be formed by the through-hole 10a.

In the case of the anodized film, since vertical pores exist, vacuum pressure may be generated in the vertical direction, so that the micro LEDs 100 may be adsorbed without having a separate through-hole 10a. Therefore, the pores of the anodized film may respectively form vacuum suction paths for adsorbing the micro LEDs 100.

However, the present invention is provided with the through-hole 10a capable of generating relatively larger vacuum pressure than that of the pore of the anodized film so that the micro LEDs 100 may be adsorbed more effectively, whereby vacuum suction paths 10a for substantially adsorbing the micro LEDs 100 respectively may be formed. As described above, since the through-hole 10a forms the vacuum suction path 10a, the same reference numeral is given to be described.

The buffer part 20 for mitigating the shock when the micro LEDs 100 are adsorbed may be provided on the surface of the anodized film, which is the body part 10. The buffer part 20 is provided on the surface of the anodized film so that when the micro LEDs are adsorbed, the shock of the micro LEDs 100 is mitigated between the micro LED adsorption body 1 and the micro LEDs 100, whereby the damage of the micro LEDs 100 may be prevented.

The buffer part 20 may be provided in a form having a plurality of openings 20a and non-opening parts or provided in an independent form surrounding the periphery of the through-hole 10a and being provided only on at least a part of the surface of the body part 10. In the case of the buffer part 20 provided in the independent form, the buffer part 20 may be formed to surround the periphery of a through-hole 10a on the surface of the body part 10, thereby having an opening 20a.

The opening 20a of the buffer part 20 as described above may have an area corresponding to the through-hole 10a. The through-hole 10a may be formed to be larger than the width of a pore of the anodic oxide layer and smaller than the horizontal area of the upper surface of each micro LED 100. Accordingly, the opening 20a of the buffer part 20 may be formed to be larger than the width of the pore of the anodic oxide layer and smaller than the horizontal area of the upper surface of each micro LED 100. For this reason, when micro LEDs 100 are adsorbed with the micro LED adsorption body 1″, the micro LEDs 100 do not come into direct contact with the surface of the body part 10, but come into contact with the surface of the buffer part 20. Due to this reason, the problem of damaging the micro LEDs 100 may be prevented.

Meanwhile, the opening 20a of the buffer part 20 may be formed to be smaller than the horizontal area of the upper surface of each micro LED 100 and smaller than the width of the through-hole 10a. In this case, the buffer part 20 may prevent the micro LEDs 100 from directly contacting the surface of the body part 10 while sufficiently generating a vacuum adsorption force for respectively adsorbing the micro LEDs 100 through the openings 20a.

When provided on the surface of the body part 10 by having the plurality of openings 20a and non-opening parts, the buffer part 20 may be implemented in the form shown in FIG. 10. In this case, the buffer part 20 is provided on the surface of the anodized film, which is the body part 10, so as to block the pores with the non-opening parts and to generate a large vacuum adsorption force capable of adsorbing the micro LEDs 100 through the openings 20a.

Meanwhile, the buffer part 20 may be provided in the independent form configured to surround the periphery of the through-hole 10a and provided only on at least a part of the surface of the body part 10. Since a plurality of through-holes 10a is formed in the anodized film that is the body part 10, a plurality of independent buffer parts 20 may be provided to respectively correspond to the through-holes 10a.

The opening 20a of the independent buffer part 20 may be formed to be smaller than the horizontal area of the upper surface of each micro LED 100 and the same as the width of the through-hole 10a, or may be formed to be smaller than the horizontal area of the upper part of each micro LED 100 and smaller than the width of the through hole 10a. When the micro LEDs 100 are adsorbed, between the micro LED adsorption body 1 and the micro LEDs 100, the buffer part 20 as above may be in direct contact with the micro LEDs 100 so that the shock generated when the micro LEDs 100 are adsorbed may be mitigated.

The buffer part 20 as above may or may not have adhesive strength on its exposed surface.

The fact that there is the adhesive strength on the exposed surface of the buffer part 20 means that the micro LED adsorption body 1″ of the third exemplary embodiment has adhesive strength on the exposed surface of the buffer part 20 in direct contact with the micro LEDs 100. Therefore, even when the vacuum adsorption force of the micro LED adsorption body 1″ with respect to the micro LEDs 100 is relatively weak, the micro LEDs 100 may be easily adsorbed, so that the micro LEDs 100 may be more effectively adsorbed in terms of adsorption of the micro LEDs 100.

Meanwhile, in a case where there is no adhesive strength on the exposed surface of the buffer part 20, when the micro LEDs 100 of the first substrate (e.g., growth substrate 101) are adsorbed and transferred to the second substrate (e.g., display substrate 301), the micro LED adsorption body 1″ of the third exemplary embodiment may easily remove the micro LEDs 100 only by releasing vacuum of the micro LED adsorption body 1″. Therefore, it may be more effective in terms of removing the micro LEDs 100.

The buffer part 20 may be configured to include a metal material. The buffer unit 20 made of a metal material may remove the electrostatic force generated during the process of adsorbing and transferring the micro LEDs 100 with the micro LED adsorption body 1″. The micro LED adsorption body 1″ of the third exemplary embodiment is provided with the buffer part 20 as described above so as to remove negative elements that prevent the transfer in the process of absorbing and transferring the micro LEDs 100, whereby the effect of increasing the transfer efficiency may be obtained.

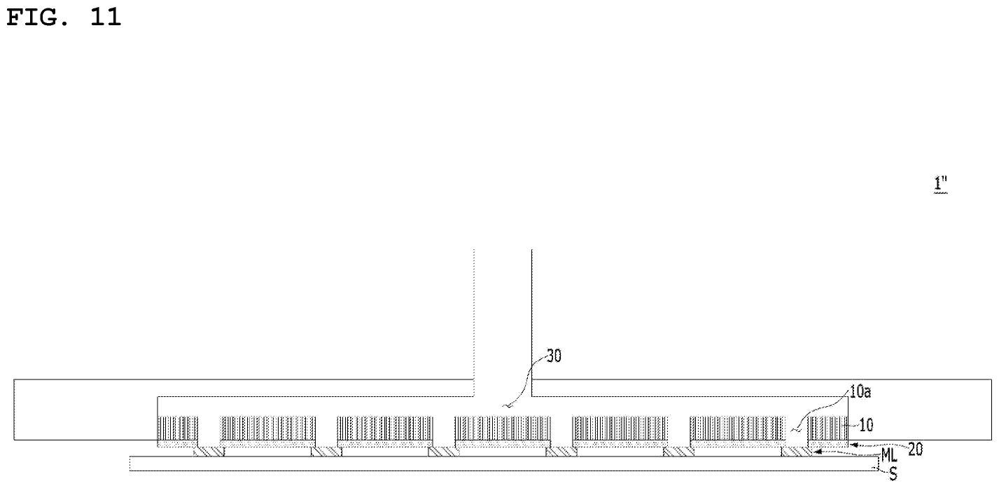

FIG. 11 is a view schematically showing a micro LED adsorption body 1″ according to a modified example of the third exemplary embodiment of the present invention. The modified example of the third exemplary embodiment is different from the third exemplary embodiment in that the pitch interval of the through-holes 10a provided in the anodized film, which is the body part 10, is different. Since all configurations except for this configuration are the same, a description of the same configuration will be omitted.

As shown in FIG. 11, in the micro LED adsorption body 1″ of the modified example, a through-hole 10a that is a vacuum suction path 10a may be provided with a distance three times the pitch interval in the column direction of the through-hole 10a, which is the vacuum suction path 10a of the micro LED adsorption body 1″ of the third exemplary embodiment shown in FIG. 10.

In the case of the third modified example shown in FIG. 11, the buffer part 20 in which the openings 20a are formed at the same pitch intervals as in FIGS. 5 and 7 may be provided.

Alternatively, the buffer part 20 surrounds the periphery of the opening of each vacuum suction path 10a and is provided only on at least a part of the surface of the anodized film, which is the body part 10, so that the plurality of buffer parts 20 may be provided in an independent form.

The micro LED adsorption body 1″ of the modified example adsorbs micro LEDs 100 by varying the pitch interval of the through-hole 10a, and may be provided with the buffer part 20 according to the changed pitch interval of the through-hole 10a. According to such a configuration, in the micro LED adsorption body 1″ having the through-hole 10a of the modified example, the micro LEDs 100 with the same emission color and mounted on the second substrate (e.g., display substrate 301) are transferred by separating the micro LEDs 100 at 3P(n) intervals, or by separating the micro LEDs 100 at 3P(n) and 3P(m) intervals, so that the micro LEDs 100 may be transferred in a diagonal direction.

As described above, the present invention is provided with the buffer part 20 on the surface of the body part 10 where the vacuum adsorption force for adsorbing the micro LEDs 100 is generated, so that when adsorbing the micro LEDs 100, the buffer part 20 may be positioned between the micro LED adsorption body 1 and the micro LEDs 100. Due to this structure, when the micro LEDs are adsorbed, the surface of the buffer part 20 and the micro LEDs 100 may be in direct contact, and the problem of damaging the micro LEDs 100 that is in direct contact with the surface of the body part 10 may be prevented. As a result, it is possible to obtain the effect of lowering a breakage rate of the micro LEDs 100 and increasing the transfer efficiency of the micro LED adsorption body 1, 1′, and 1″.

As described above, although the present invention has been described with reference to the preferred exemplary embodiment, those skilled in the art may implement the present invention by various modifications or variations within the scope without departing from the spirit and scope of the present invention as set forth in the following claims.

### DESCRIPTION OF THE REFERENCE NUMERALS IN THE DRAWINGS

1, 1′, 1″: micro LED adsorption body

10: body part 10a: through-hole or vacuum suction path

20: buffer part 20a: opening

30: vacuum chamber 100: micro LEDs

1. A micro LED adsorption body configured to adsorb micro LEDs with vacuum suction force, the micro LED adsorption body comprising:
a body part provided with a vacuum suction path; and
a buffer part provided on a surface of the body part to mitigate a shock when the micro LEDs are adsorbed.

2. The micro LED adsorption body of claim 1, wherein the body part is a non-porous member through which the vacuum suction path penetrates upward and downward.

3. The micro LED adsorption body of claim 1, wherein the body part is a porous member.

4. The micro LED adsorption body of claim 3, wherein the porous member has random pores.

5. The micro LED adsorption body of claim 3, wherein the porous member has vertical pores.

6. The micro LED adsorption body of claim 5, wherein the porous member is formed of an anodized film having the vertical pores, and
a through-hole having a width greater than the width of each pore forms the vacuum suction path.

7. The micro LED adsorption body of claim 1, wherein an exposed surface of the buffer part has adhesive strength.

8. The micro LED adsorption body of claim 1, wherein an exposed surface of the buffer part has no adhesive strength.

9. The micro LED adsorption body of claim 1, wherein the buffer part comprises a metal material.

10. A micro LED adsorption body, comprising:
a body part provided with an anodized film having a pore and a through-hole penetrating the anodized film; and
a buffer part provided on a surface of the body part to mitigate a shock when micro LEDs are adsorbed.

11. The micro LED adsorption body of claim 10, wherein an opening of the buffer part has an area corresponding to that of the through-hole.
